(19) United States
(12) Patent Application Publication
(10) Pub. No.: US 2006/0035458 A1
(43) Pub. Date: Feb. 16, 2006

(54) Semiconductor element

(75) Inventors: Peter Nelle, Muenchen (DE); Renate Hofmann, Muenchen (DE); Jorg Busch, Regensburg (DE); Alfred Edtmair, Bad Abbach (DE); Manfred Schneegans, Vaterstetten (DE); Matthias Stecher, Muenchen (DE)

Correspondence Address: Maginot, Moore & Beck;Suite 3000, Bank One Tower, 111 Monument Circle, Indianapolis, IN, 46204, US

(73) Assignee: Infineon Technologies AG, Munchen (DE)

(21) Appl. No.: 11/191,150

(22) Filed: Jul. 26, 2005

(30) Foreign Application Priority Data
Jul. 26, 2004 (DE) 102004036140.1-33

(51) Int. Cl. H01L 21/4763

(52) U.S. Cl. 438/624

(57) ABSTRACT

The invention relates to a semiconductor component having a semiconductor body (1), to which a metallization (10), which is formed from metallization layers (11, 13, 15, 17) and separating layers (12, 14, 16, 18) arranged alternately in succession, a dielectric (2) and a molding compound (3) joined to the dielectric (2) are applied alternately in succession.

The invention relates to a semiconductor component having a semiconductor body, on which a metallization, a dielectric and a molding compound, which forms the housing of the semiconductor body, are arranged in succession, the molding compound being joined to the dielectric.

Problems may arise if the semiconductor component is subject to frequent and major temperature changes. Major temperature changes occur in particular in pulsed operation, for example if the temperature of the semiconductor component rises to 250° C. to 300° C. for a period of, for example, 1 ms as result of the current pulse every 10 ms, and then cools back down to room temperature.

One of the main problems in this respect is stress cracks, which can occur as a result of different coefficients of thermal expansion of the semiconductor body, the metallization, the dielectric and the housing compound.

Cracks of this type in the dielectric, for example a passivation layer, can lead to short circuits and corrosion as a result of the penetration of moisture, which in the medium term leads to failure of the semiconductor component, thereby shortening its service life.

One main reason for the formation of stress cracks of this nature is that the metallization, which is typically formed from aluminum, copper or alloys of these elements, on account of its ductility, is plastically deformed to an ever greater extent with each temperature cycle, with the result that the shear forces acting on the dielectric increase with each temperature cycle. These shear forces and the associated mechanical stresses, in particular tensile stresses, can then lead to the abovementioned cracks in the dielectric.

It is also possible for material of the metallization, e.g. aluminum, to penetrate into these stress cracks on account of its ductility, thereby causing short circuits.

To avoid the occurrence of stress cracks of this nature, some semiconductor components have a soft buffer layer, for example of polyimide, arranged between the molding compound and the dielectric; the intention is that the abovementioned mechanical stresses should be at least sufficiently reduced within the buffer layer to ensure that there is no damage to the dielectric. However, in practice, stress cracks of this nature do nevertheless occur in the dielectric.

Therefore, the object of the present invention is to improve a semiconductor component of the type described in the introduction in such a way that cracks of this nature do not occur in the dielectric, and as a result, the service life of the semiconductor component is lengthened.

This object is achieved by a semiconductor component in accordance with claim 1. Advantageous embodiments and refinements of the invention form the subject matter of subclaims.

The semiconductor component according to the invention has a semiconductor body, to which a metallization, a dielectric and a molding compound joined to the dielectric are successively applied. The metallization is formed from metallization layers and separating layers arranged alternately in succession.

According to a preferred embodiment of the invention, the molding compound is joined directly to the dielectric at least in sections.

The metallizations serve primarily to produce connections of good electrical conductivity. To achieve a defined current-carrying capacity, therefore, metallizations, in particular for power semiconductor components, are formed with a relatively great thickness. As explained in more detail below, however, the use of thick metallizations with a good conductivity, under the action of strong and frequent temperature fluctuations, with the associated thermal changes in length, reduces the ductility and flow properties of these metallizations to a greater extent than if thin metallization layers of the same material are used.

To avoid the concomitant drawbacks, it is provided in the present invention for the metallization to be constructed as a layer sequence comprising a plurality of metallization layers and separating layers. For this purpose, metallization layers and separating layers are arranged alternately in succession, with the metallization layers serving predominantly to carry current, whereas the separating layers are predominantly intended to separate the metallization layers from one another.

Although EP 0 253 299 A1 has disclosed a metallization for integrated circuit arrangements with a sandwich-like structure, neither a dielectric nor a molding compound joined to this dielectric is arranged on this metallization. The sandwich-like structure is intended primarily to achieve a higher current-carrying capacity and to avoid the formation of hillocks.

Furthermore, the metallization shown in EP 0 253 299 A1 has a layer of platinum silicide, which is arranged between a silicon layer and a metallization. In the subject matter of the present invention, a platinum silicide layer of this type is not required. Instead, a layer arranged between the semiconductor material and the metallization can be eliminated altogether, i.e. the metallization may be joined directly to the semiconductor body at least in sections. However, it is also possible for a layer of other materials, e.g. of Ti, TiN, Al, AlSi or AlSiCu, to be arranged between the semiconductor body and the metallization at least in sections.

Suitable separating layers are in principle all electrically conductive materials, preferably titanium, tungsten, tantalum, copper, gold, silver or alloys of at least one of these metals, for example titanium nitride, titanium tungsten, or tantalum nitride. However, zinc oxide, graphite or other non metallic conductors can also be used as material for the separating layer. In this context, it is possible to form different separating layers from different materials. The electrical resistivity of the separating layers is preferably less than 25 μΩ·m, particularly preferably less than 2.5 μΩ·m.

By contrast, the metallization layers are preferably formed from materials of good electrical conductivity, for example from aluminum, copper, gold, silver, tungsten or an alloy of at least one of these metals, it being possible for different metallization layers to be formed from different metals. The electrical resistivity of a metallization layer is preferably less than 0.06 μΩ·m, for example in the case of tungsten approximately 0.054 μΩ·m, particularly preferably less than 0.03 μΩ·m, for example in the case of copper approximately 0.017 μΩ·m or in the case of aluminum approximately 0.027 μΩ·m.

With the layered structure of the metallization, the metallization layers are separated from one another by means of thin separating layers.

As has been mentioned above, a change in the thickness of a metallization layer also leads to a change in its physical properties, such as flow properties or ductility. The thinner the metallization layer which is formed, the harder it is and the lower its ductility, and consequently the lower its tendency to flow.

Consequently, the changes in the metallization which were mentioned in the introduction, in particular as a result of temperature changes, can be significantly reduced by means of a layered structure, as described above, of the metallization. As a result, the magnitude of the mechanical stresses acting on the dielectric are limited, with the result that the probability of cracks forming in a dielectric joined to the metallization is significantly reduced.

According to a preferred embodiment, the dielectric is formed as a layer, for example as a passivation layer or as an oxide layer. The dielectric is typically formed from brittle material, for example from silicon nitride or silicon oxynitride or silicon dioxide.

The preferred thicknesses of the separating layers are between 1 nm and 40 nm, particularly preferably between 1 nm and 30 nm, while the preferred thicknesses of the metallization layers are between 1 nm and 1000 nm, particularly preferably between 10 nm and 1000 nm.

According to a further preferred embodiment, the ratio between the thickness of the metallization layers and the thickness of the separating layers should be between 1 and 1000. The metallization overall has a thickness of preferably between 500 nm and 500 μm.

The layered structure of the metallization allows flow stresses of the metallization of over 200 MPa or even over 300 MPa to be achieved.

With the metallization which has been constructed in layered form in the manner described, it is possible to combine the mechanical properties of the separating layers with the good conductor properties of the metallization layers.

The invention is explained in more detail below with reference to the appended figures, in which:

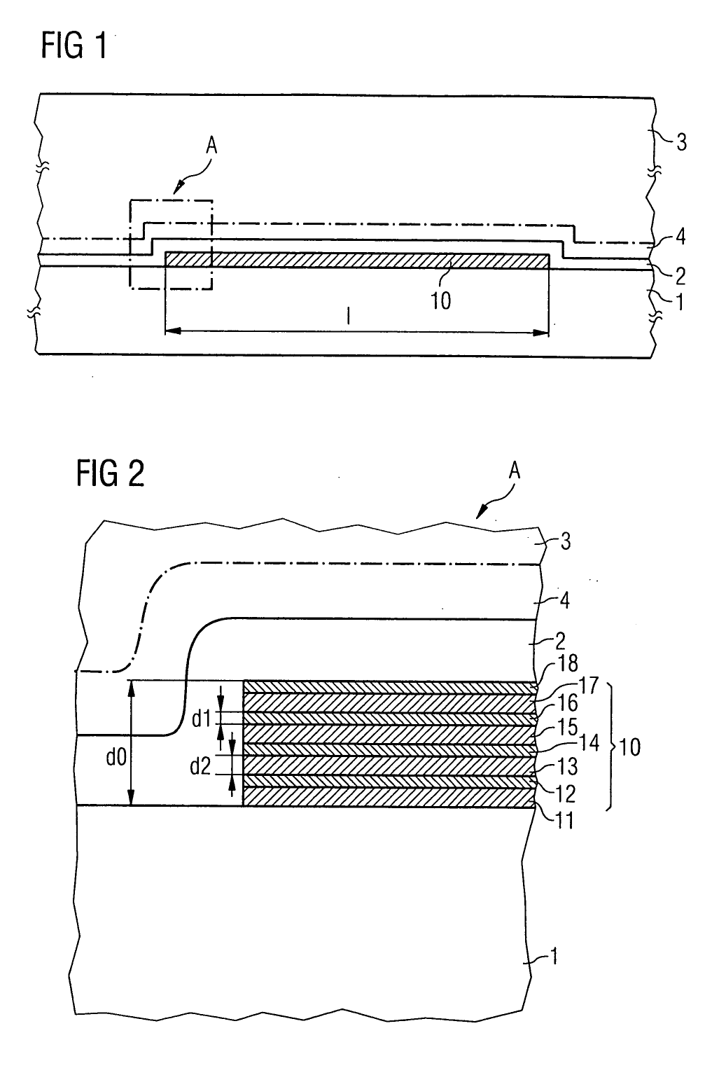

FIG. 1 shows a cross section through an excerpt from a semiconductor component according to the invention with a molding compound joined to a dielectric;

FIG. 2 shows an enlarged part of the semiconductor component according to the invention as shown in FIG. 1,

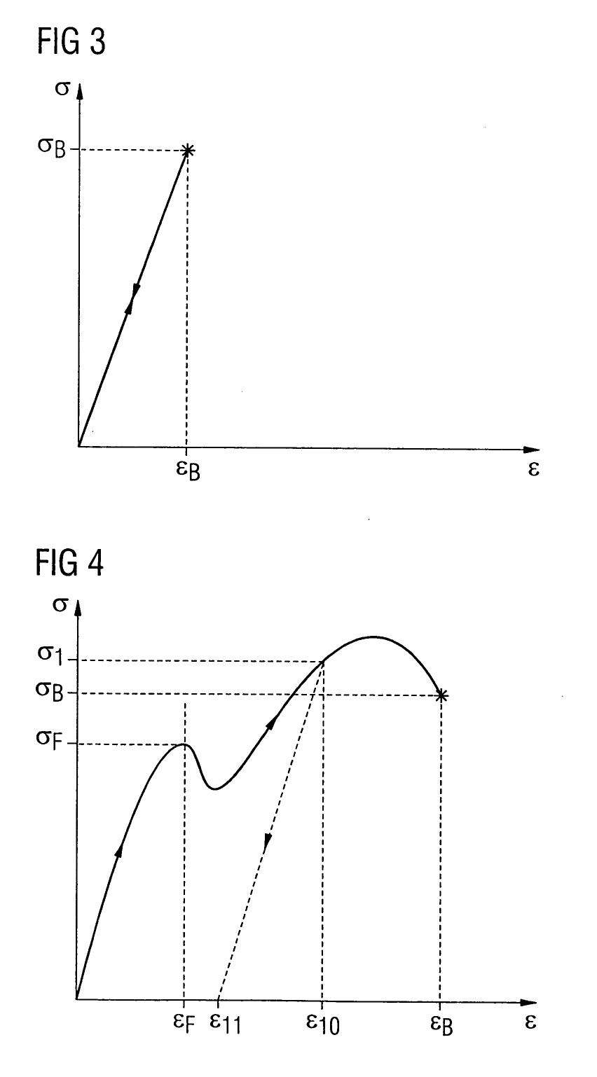

FIG. 3 shows a stress-strain curve of a brittle dielectric,

FIG. 4 shows a stress-strain curve of a ductile metal, and

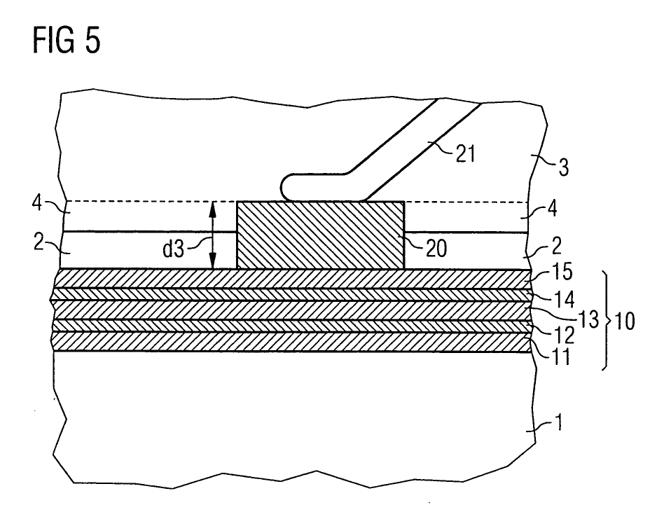

FIG. 5 shows an enlarged portion of a semiconductor component according to the invention as shown in FIG. 2, in which the metallization has a bonding metallization joined to a bonding wire.

In the figures, identical reference numerals denote identical parts with the same meaning.

FIG. 1 shows an excerpt from a semiconductor component according to the invention and a semiconductor body 1, on which a metallization 10 of length l is arranged. The metallization 10 may, for example, form an interconnect or a surface terminal contact of the semiconductor component. A dielectric 2 and a molding compound 3 which forms the housing of the semiconductor component have been applied to the metallization 10. The dielectric 2 and the molding compound 3 are directly joined securely to one another at least in sections. The dielectric 2 serves, for example, as a passivation layer.

With the structure shown, it is optionally possible for a buffer layer 4 illustrated in dashed lines, for example of polyimide, to be arranged between the dielectric 2 and the molding compound 3. However, the dielectric 2 and the molding compound 3 may also be joined to one another directly or indirectly but without a buffer layer 4 of this type, at least in sections.

FIG. 2 shows an enlarged illustration of the region A indicated by dashed lines in FIG. 1. It can be seen from this illustration that the metallization 10 arranged on the semiconductor body 1 is formed from a number of layers 11-18. These layers 11-18 comprise separating layers 12, 14, 16, 18 and metallization layers 11, 13, 15, 17. These layers 11-18 together form the metallization 10.

According to a preferred embodiment of the invention, the separating layers 12, 14, 16, 18 are formed from titanium, titanium nitride, titanium tungsten, tungsten, tantalum, tantalum nitride, copper, gold or silver. The thickness d1 of the separating layers 12, 14, 16, 18 is preferably less than 40 nm and particularly preferably between 1 nm and 30 nm.

The metallization layers 11, 13, 15, 17 are preferably formed from metals of good electrical conductivity, such as aluminum, copper, gold, silver, from tungsten or an alloy of these metals. The thickness d2 of the metallization layers 11, 13, 15, 17 is preferably from 1 nm to 1000 nm, and the total thickness d0 of the metallization 10 is preferably between 500 nm and 50 μm.

The thinner a layer 11-18 is designed to be, the lower its ductility and the lower also the change in the materials properties described in the introduction caused by the ductility of the corresponding layer 11-18 under the action of temperature fluctuations. With regard to the present invention, this fact is of relevance in particular to the metallization layers 11, 13, 15, 17.

The top layer, furthest away from the semiconductor body 1, of the metallization 10 may—as illustrated in FIG. 2—be in the form of a separating layer 18. However, it is equally possible for the top layer to be a metallization layer. Accordingly, it is also possible for the bottom layer, closest to the semiconductor body 1, of the metallization 10 to be in the form both of a metallization layer and of a separating layer.

The text which follows describes the change in the ductility and flow properties of materials caused by the action of temperature fluctuations and associated changes in length, with reference to the stress-strain curves illustrated in FIGS. 3 and 4.

The simplest case of a stress-strain curve of this type is illustrated in FIG. 3 and applies to brittle materials, as are typically used as dielectric 2. The curve shows the mechanical stress a of the material in question as a function of its strain ε. If the material in question, in the stress-free state, has a length l0 in a defined direction, and if its length changes by Δl under the action of an external stress σ, the strain ε is equal to the ratio Δl:10. Typical lengths l0 for a metallization are between 0.5 μm and 20 mm and typical values for the strain ε are between 0.001 and 0.01.

As can be seen from the stress-strain curve illustrated in FIG. 3, the stress σ rises at least approximately linearly with increasing strain ε starting from the stress-free state. If the strain ε exceeds a defined value ε_{B}, the material in question undergoes spontaneous stress fracture at the associated fracture stress σ_{B}. The strain in this material is reversible for as long as the strain remains lower than the fracture stress ε_{B}, i.e. after the stress has been relieved following prior strain, the material returns to the original length l0.

The stress-strain properties of ductile materials, from which, for example, the metallization layers 11, 13, 15, 17 are formed, are different. Typical representatives of materials of this type are, for example, aluminum, copper or their alloys. If the strain ε of a material of this type remains below the flow limit ε_{F}, the strain is reversible. However, if the strain exceeds this flow limit ε_{F}, for example up to a strain ε₁₀, this strain is irreversible. Specifically, if the stress σ is reduced back to zero, corresponding to the stress-free state, a strain ε₁₁, remains.

The physical properties of the material in question have changed as a result. A new stress-strain curve, the profile of which in qualitative terms corresponds to the stress-strain curve shown in FIG. 4, now applies to this material which has been altered in this way. Consequently, with each renewed strain above the respective flow limit ε_{F}, further changes in the associated materials properties, i.e. in particular the ductility and the flow properties, may be caused accordingly, as is the case with a metallization in accordance with the prior art in the event of a multiplicity of successive temperature changes, with the associated strains and relieving of stresses.

The layered structure of the metallization 10 according to the invention shifts the flow limit ε_{F} of the metallization 10 toward higher values. For example, it was possible to demonstrate on the basis of model calculations that the flow stress ε_{F} of the metallization 10 of a semiconductor component according to the invention with a thickness of the metallization 10 of 2 μm is approximately 300 MPa with a flow limit ε_{F} of 0.0042. By comparison, a typical value for the flow stress σ_{F} of a metallization of the same thickness in accordance with the prior art, formed from pure aluminum, AlSi or Al—SiCu, is only approximately 100 MPa, i.e. approximately one third of the flow stress of the metallization 10 according to the invention constructed in layered form. The metallization on which the model calculations is based has two metallization layers of aluminum with a thickness of in each case 500 nm and one separating layer of titanium with a thickness of 10 nm arranged between the two metallization layers.

The thicknesses d2 of the metallization layers 11, 13, 15, 17 illustrated in FIG. 2 are therefore preferably selected in such a way that the fracture stress of the dielectric 2 is not reached even in the event of relatively major temperature changes, for example during cooling from 180° C. to −50° C. On the other hand, in particular in the case of power semiconductor components, it should be ensured that the current-carrying capacity and the overall electrical resistance of the structured metallization 10 are not excessively reduced by the structuring. This can be achieved in particular by using a suitable number of metallization layers 11, 13, 15, 17.

That one of the layers 11-18 which is closest to the semiconductor body 1 may be either a separating layer 12, 14, 16, 18 or, as illustrated in FIG. 2, a metallization layer 11, 13, 15, 17. Accordingly, the layer of the metallization 10 which is furthest away from the semiconductor body 1 may be either a metallization layer 11, 13, 15, 17 or, as illustrated in FIG. 2, a separating layer 12, 14, 16, 18.

A metallization 10 of a semiconductor component according to the invention has at least two metallization layers 11, 13, 15, 17, between which a separating layer 12, 14, 16, 18 is arranged. The preferred number of layers for a metallization 10 is 1, 2, 3 or 4 separating layers 12, 14, 16, 18 and 2, 3, 4 or 5 metallization layers.

The separating layers are used primarily to separate the metallization layers from one another. The thickness of the separating layers should be selected to be as thin as possible, but at least sufficiently thick for them still to remain in layer form, rather than being dissolved as a result of diffusion phenomena, even after a number of temperature change cycles have been passed through, as typically occur when commissioning or carrying out function tests on a semiconductor component according to the invention.

Bonding connections are often used for contact-connection of metallizations of a semiconductor component. However, the quality and durability of bonding connections of this type is dependent, inter alia, on the thickness of the material onto which the bonding connection is carried out. Since the metallization layers of a metallization according to the invention are preferably very thin in form, according to a preferred embodiment of the invention, there is provision for one of the layers of the metallization, which is to be contact-connected by means of a bonding connection, to be provided with a bonding metallization.

An arrangement of this type is shown in FIG. 5. A metallization 10 which includes metallization layers 11, 13, 15 which are separated from one another by separating layers 12, 14 is arranged on the semiconductor body 1.

A bonding metallization 20 with a thickness d3 is arranged on the top metallization layer 15. The bonding metallization 20 is preferably joined directly to the metallization 10, particularly preferably to its top metallization layer 15.

A bonding connection is formed between the bonding metallization 20, which is preferably designed as a bonding pad with a surface area of between 30 μm×30 μm and 500 μm×500 μm, and a bonding wire 21. The thickness d3 of the bonding metallization 20 is selected in such a way as to ensure a permanent connection. The thickness d3 is preferably greater than 0.5 μm, and is particularly preferably between 1 μm and 50 μm. The bonding metallization 20 is preferably formed from nickel or a nickel alloy and can be produced, for example, by means of an electroless deposition process. Other materials which are preferentially used for bonding metallizations include gold, silver or palladium.

Moreover, a dielectric 2, which preferably extends onto the bonding metallization 20 and totally surrounds the bonding metallization in the lateral direction, is arranged on the metallization 10. Furthermore, a molding compound 3, which forms the housing of the semiconductor component, is arranged on the dielectric 2. A buffer layer 4 may optionally be arranged between the dielectric 2 and the molding compound 3, in accordance with the semiconductor components shown in FIGS. 1 and 2.

### List of Designations

1 semiconductor body
2 dielectric
3 molding compounds
4 buffer layer
10 metallization
11, 13, 15, 17 metallization layer
12, 14, 16, 18 separating layer
20 bonding metallization
21 bonding layer
d0 thickness of the metallization
d1 thickness of the separating layer
d2 thickness of the metallization layer
d3 thickness of the bonding metallization
l, l0 length of the metallization
Δl change in length of the metallization
ε, ε_{B}, ε_{F}, ε₁₁, ε₁₀ strain
σ, σ_{B}, σ₁ stress

1-23. (canceled)

24. An arrangement for use on a semiconductor body, the arrangement comprising:
a metallization comprising metallization layers and separating layers arranged alternately in succession;
a dielectric disposed at least in part over at least a part of the metallization layer; and
a molding compound joined to the dielectric.

25. The arrangement as claimed in claim 24, wherein the dielectric and the molding compound are directly joined to one another at least in sections.

26. The arrangement as claimed in claim 24, further comprising a polyimide layer arranged between at least a part of the dielectric and at least a part of the molding compound.

27. The arrangement as claimed in claim 24, wherein at least one of the separating layers is formed from, at least in part, at least one of the group consisting of titanium, titanium nitride, titanium tungsten, tungsten, tantalum, tantalum nitride, copper, gold, silver, an alloy of titanium, an alloy of titanium nitride, an alloy of titanium tungsten, an alloy of tungsten, an alloy of tantalum, an alloy of tantalum nitride, an alloy of copper, an alloy of gold, an alloy of silver, zinc oxide and graphite.

28. The arrangement as claimed in claim 24, wherein a thickness of at least one of the separating layers is less than 40 nm.

29. The arrangement as claimed in claim 24, wherein a thickness of at least one of the separating layers is between 1 nm and 30 nm.

30. The arrangement as claimed in claim 24, wherein at least one of the separating layers has an electrical resistivity of less than 25 micro-ohms.

31. The arrangement as claimed in claim 24, wherein at least one of the separating layers has an electrical resistivity of less than 2.5 micro-ohms.

32. The arrangement as claimed in claim 24, wherein at least one of the metallization layers has an electrical resistivity of less than 0.03 micro-ohms.

33. The arrangement as claimed in claim 24, wherein at least one of the metallization layers at least one of the group consisting of aluminum, copper, tungsten, an alloy of aluminum, an alloy of copper and an alloy of tungsten.

34. The arrangement as claimed in claim 24, wherein a thickness of at least one of the metallization layers is between 1 nm and 500 nm.

35. The arrangement as claimed in claim 24, wherein a thickness of the metallization is between 0.5 μm and 50 μm.

36. The arrangement as claimed in claim 24, wherein the metallization has a flow stress of at least 200 MPa.

37. The arrangement as claimed in claim 24, wherein the metallization has a flow stress of at least 300 MPa.

38. An arrangement for use on a semiconductor body, the arrangement comprising:
at least two metallization layers and at least one separating layer arranged alternately in succession,
a dielectric disposed at least in part over at least a part of the at least two metallization layers; and
a molding compound disposed adjacent to the dielectric.

39. The arrangement as claimed in claim 38 wherein the at least one separating layer comprises between two and four separating layers.

40. The arrangement as claimed in claim 38 wherein a thickness of at least one separating layer is less than 40 nm.

41. The arrangement as claimed in claim 38, wherein the dielectric is in the form of an oxide layer.

42. The arrangement as claimed in claim 38, wherein the dielectric is in the form of a passivation layer.

43. The arrangement as claimed in claim 38, wherein the dielectric includes at least one of the group consisting of silicon nitride, silicon oxynitride and silicon dioxide.

44. The arrangement as claimed in claim 38, wherein the dielectric is formed from brittle material.

45. The arrangement as claimed in claim 38, wherein a first layer is arranged between the semiconductor body and the at least two metallization layers, the first layer including at least one of the group consisting of titanium (Ti), titanium nitride (TiN), aluminum (Al), aluminum-silicon (AlSi) and aluminum-silicon-copper (AlSiCu).

46. The arrangement as claimed in claim 24, wherein a bonding metallization is arranged on the metallization.
